(19) United States
(12) Patent Application Publication
(10) Pub. No.: US 2007/0114662 A1
(43) Pub. Date: May 24, 2007

(54) Interconnecting element between semiconductor chip and circuit support and method

(76) Inventors: Johann Helneder, Landsham (DE); Manfred Schneegans, Vaterstetten (DE); Holger Torwesten, Regensburg (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/600,694

(22) Filed: Nov. 16, 2006

(30) Foreign Application Priority Data
Nov. 17, 2005 (DE) 10 2005 055 280.3

(51) Int. Cl. H01L 23/48; H01L 21/00

(52) U.S. Cl. 257/737; 257/778; 438/108; 257/E23.021

(57) ABSTRACT

One aspect of the invention relates to an interconnecting element between a semiconductor chip of a semiconductor wafer and a circuit support and to a method for producing and using the interconnecting element. Such interconnecting elements are arranged between contact areas of a semiconductor chip of a semiconductor wafer and contact terminal areas of a circuit support. The contact areas on the semiconductor chip or the semiconductor wafer, respectively, are arranged in depressions of a top of an insulating cover layer and are freely accessible. The interconnecting elements have a mushroom shape with a mushroom cap in a first metal area. On the mushroom cap of the first metal area, a second metal area is arranged which has high-melting intermetallic phases of metals of a solder material and the metal of the contact terminal areas of the circuit support.

### CROSS-REFERENCE TO RELATED APPLICATIONS

This Utility Patent Application claims priority to German Patent Application No. DE 10 2005 055 280.3, filed on Nov. 17, 2005, which is incorporated herein by reference.

### BACKGROUND

One embodiment of the invention relates to an interconnecting element between a semiconductor chip of a semiconductor wafer for semiconductor components and a circuit support, and to a method for producing and using the interconnecting element. The miniaturization of discrete semiconductor components such as diodes and transistors and the pressure of prices for such standardized semiconductor components continuously require new and revised solutions for the package configuration.

In the package configuration, a distinction is made between packages which are based on a lead frame, such as for example the SOT, SOD, SC and/or TSFP packages, and packages which are not based on a lead frame, the so-called lead-free packages such as, for example, the BGA (ball grid array) packages, or TSLP packages. These current solutions for providing package configurations for semiconductor components have the disadvantage that they are based on processes such as die bonding and wire bonding, where it is disadvantageously necessary to provide corresponding semiconductor chip terminal areas for applying the semiconductor chips and corresponding contact terminal areas for attaching the bonding wires to a circuit support.

These components reduce the possibility of improving the packages with respect to miniaturization. Thus, it is not possible to reduce the package height arbitrarily since the thickness of the contact terminal areas and the thickness of the semiconductor chip contact areas and the thickness of the semiconductor chip and the height of the bonding wire loops and the height of the plastic package compound for embedding the bonding wires must be taken into consideration.

In the miniaturization of the lateral dimensions, limits are set to the semiconductor components since sufficient space must be taken into consideration for the tolerances of the semiconductor chip bonding, for the tolerances of the lengths of the bonding wires and for the tolerances of the wall thicknesses of the molding compounds. As a result, the possibility for miniaturization is exhausted with respect to length, width and height of the packaged semiconductor component in the case of dimensions below a half millimeter, especially in the case of discrete semiconductor components.

From the printed document U.S. Pat. No. 6,197,613 B1, a method for forming a package on semiconductor wafer basis is known in which initially a silicon wafer is provided which has a multiplicity of integrated circuit chips which are formed on the top of the semiconductor wafer. Each of these integrated circuit chips has a number of I/O contact areas distributed over the circumference which are arranged in an insulating layer. These contact areas are connected electrically with solder balls as flip chip contacts via through contacts through an elastic layer and via conductor tracks on the elastic layer. The semiconductor components produced by means of this method in the order of magnitude of semiconductor chips have the disadvantage that their package height cannot be arbitrarily reduced due to the solder ball and the elastic layer arranged underneath.

From printed document U.S. Pat. No. 6,518,097 B1, a method for producing flip chip packages on semiconductor wafer basis using an anisotropically conductive adhesive is known. For this purpose, a bump free of solder material such as a bump of gold is produced on the contact areas of each semiconductor chip of a semiconductor wafer. An anisotropically conductive adhesive solution or a film is arranged on the wafer and then the semiconductor wafer is separated into individual semiconductor chips.

Each of the semiconductor chips is mechanically or electrically connected to a substrate via the anisotropically conductive adhesive. This method has the disadvantage that interconnecting elements are formed which cannot be detachably connected to a substrate. In addition, the method has the disadvantage that connecting the bump with a substrate requires a special anisotropically conductive adhesive or an anisotropically conductive foil which restricts both the costs of the method and the usability of such a semiconductor component package for discrete semiconductor components.

A further known technique consists in minimizing component heights, in which flip chip contacts are arranged on the contact areas in the form of solder balls of lead-free soldering material for which purpose the lead normally used is replaced by silver in a tin solder. Such solder balls have the disadvantage that they react with the material of the contact areas, which are usually of aluminum, and become brittle so that the semiconductor components equipped with such interconnecting elements fail early in cyclic thermal tests. Due to different coefficients of thermal expansion of the semiconductor chips and of the circuit supports, the interconnecting elements are subject to strong thrust and shear stresses during the cyclic thermal loading. These mechanical loads on the lead-free interconnecting elements lead to permanent damage including cracking.

In addition, alloying and/or diffusing materials of the contact areas into the solder material can lead to embrittlement in the critical transition area from the contact areas of the semiconductor chips to the interconnecting element materials. With electromigration loading, there is also the risk that aluminum metallization of the contact areas of the semiconductor chip penetrates into the solder material and the electrical resistance of the interconnecting element rises abruptly.

### SUMMARY

One aspect of the invention relates to an interconnecting element between a semiconductor chip of a semiconductor wafer and a circuit support and to a method for producing and using the interconnecting element. Such interconnecting elements are arranged between contact areas of a semiconductor chip of a semiconductor wafer and contact terminal areas of a circuit support. The contact areas on the semiconductor chip or the semiconductor wafer, respectively, are arranged in depressions of a top of an insulating cover layer and are freely accessible. The interconnecting elements have a mushroom shape with a mushroom cap in a first metal area. On the mushroom cap of the first metal area, a second metal area is arranged which has high-melting intermetallic phases of metals of a solder material and the metal of the contact terminal areas of the circuit support.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a diagrammatic cross section through a semiconductor component of an embodiment of the invention.

FIGS. 2 to 6 illustrate diagrammatic cross sections through a part-area of an interconnecting element during its production.

FIG. 2 illustrates a diagrammatic cross section through a contact terminal area of a semiconductor chip after deposition of a first and a second metal area.

FIG. 3 illustrates a diagrammatic cross section through the contact terminal area according to FIG. 2 after the second metal area has been melted on.

FIG. 4 illustrates a diagrammatic cross section through the contact terminal area of the mushroom-shaped interconnecting element.

FIG. 5 illustrates a diagrammatic cross section through the contact terminal area with interconnecting element according to FIG. 3 in an oblique section.

FIG. 6 illustrates a diagrammatic cross section through the contact terminal area after completion of the interconnecting element by soldering onto a contact terminal area of a circuit support.

FIG. 7 illustrates a diagrammatic cross section through an enlarged detail of the interconnecting element according to FIG. 5.

FIGS. 8 and 9 illustrate diagrammatic cross sections through a contact terminal area during the production of an interconnecting element by means of an alternative method.

FIG. 8 illustrates a diagrammatic cross section through the contact terminal area after application of the first and second metal area.

FIG. 9 illustrates a diagrammatic cross section through the contact terminal area after the second metal area has been melted on.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One aspect of the invention specifies an interconnecting element which can be used for packages on semiconductor chip basis, reduces the costs of the method and permits more reduced dimensions for discrete semiconductor components so that the total dimensions of the semiconductor component only insignificantly increase the dimensions of a semiconductor chip for discrete semiconductor components. One aspect of the invention increases the reliability and the service life of lead-free interconnecting elements.

According to one embodiment of the invention, interconnecting elements for a semiconductor component are created wherein the interconnecting elements are arranged between contact areas of a semiconductor chip of a semiconductor wafer and contact terminal areas of a circuit support. The contact areas on the semiconductor chip or the semiconductor wafer, respectively, are arranged in depressions of a top of an insulating cover layer and are freely accessible. The interconnecting elements have a mushroom shape of a first metal area of the interconnecting element.

This first metal area fills up the depressions in the cover layer and its mushroom cap extends beyond the respective depression to areas of the edges of the depressions on the cover layer. Furthermore, the first metal area, in one case of copper or of a copper alloy, can be arbitrarily extended by arranging additionally on the cover layer a structured photo resist layer which has respective depressions at the same positions and is removed after the deposition of the first metal area. This makes it possible to create interconnecting elements which protrude over the cover layer and have a mushroom stalk with a mushroom cap. On the mushroom head or mushroom cap, a second metal area is arranged which has high-melting intermetallic phases of metals of a solder material and of the metal of the contact terminal areas of the circuit support.

With this interconnecting element, after the semiconductor chip is connected to the circuit support via the interconnecting elements, this connection can withstand a higher process temperature than the temperature at which the second metal area was connected to the contact terminal areas of the circuit support.

The shape of the first metal area which is in contact with the contact areas of the semiconductor chip. This mushroom shape guarantees that the second material is protected against the material of the contact areas of the semiconductor chip. Especially since the first metal material with its mushroom shape in one case completely covers the depressions in which the contact areas are located and additionally also protrudes over the edge areas of the depressions. It is thus virtually impossible for the contact material of the contact areas to protrude to the solder material forming the intermetallic phases. In consequence, this first metal area remains ductile and can dampen shear stresses which usually occur with cyclic thermal loads in the case of different coefficients of expansion between semiconductor chip and circuit support without any delamination of the first metal from the metal or material of the contact terminal area occurring.

With this mushroom-shaped arrangement of the first metal area, the solder material which is then applied to this mushroom head cannot penetrate to the bottom of the mushroom head and into the depression so that intermetallic phases between the contact area material and the second metal area cannot be formed. The first metal area thus in one case completely seals the depression in the cover layer and, at the same time, due to the formation of a protruding mushroom cap, ensures that the solder material still to be applied for the second metal area cannot become mixed with the contact area material.

With this solution, the solder volume of the second metal area on the first mushroom-shaped metal area can be reduced to such an extent that the solder material can be completely mixed through with the metal of the contact terminal area of the support material and thus isothermal solidification occurs. In this process, new intermetallic phases form between the solder material and the material of the contact terminal area which increases the temperature resistance of this solder connection up to 450° C., for example, even though the soldering temperature can be about 250° C. This ensures that in subsequent soldering processes, for example of the semiconductor component onto a higher-level circuit board, no melting of the interconnecting element according to the invention between semiconductor chip and circuit support can be caused. In addition, the following are achieved by means of the interconnecting element according to embodiments of the invention:

1. The interconnecting element can have lead-containing and/or lead-free solders and exhibits high wettability of the contact terminal areas of the circuit support for both types of solder.

2. The remelting temperature is over 400° C. due to the intermetallic phases formed.

3. In the case of thermal loads, only minimal plastic deformations occur.

4. The fact that the first metal area can be wetted by the solder material ensures a selective application of the solder material and limits a deposition of the solder material to the mushroom cap and thus prevents the solder material from creeping further without having to provide an extra solder resist layer.

5. The stability under thermal cyclic loading and the migration resistance are increased since a penetration of, for example, an aluminum material of the contact areas of the semiconductor chip into the solder is prevented by the mushroom shape.

6. Compared with the previous methods working with solder balls as flip chip contacts, this technique makes it possible to achieve a distinct reduction in costs during the production since the complex alignment of solder ball matrices is completely dispensed with.

The contact areas of the semiconductor chip or of the semiconductor wafer in one case have nickel and/or aluminum and/or gold. Contact areas of aluminum are most widely used for semiconductor chips. For high-quality RF components, gold is also used because of the lower contact resistance and nickel is used when the first metal area has to have nickel, for example for an interconnecting element according to one embodiment of the invention.

In one embodiment of the invention, the first metal area of the interconnecting elements is arranged on a root area of the mushroom shape of a nickel layer on the contact areas. The diffusion-retarding nickel layer consists of a galvanically or chemically deposited nickel. Nickel on the one hand, adheres well to a semiconductor surface such as silicon but can also be deposited without problems on aluminum- or gold-containing contact terminal areas and forms a diffusion barrier.

In the case of a galvanic deposition, or also in the case of a chemical deposition determined by ion exchange, on a metallic or semiconducting contact area or a nickel layer, the deposition of the first material area, in one case of copper or of a copper alloy, can grow beyond the opening in the cover layer and form a mushroom cap, the area of extent of which is greater than the opening in the cover layer or a photo resist layer thickening the cover layer. This projection can be in one case expressed by the ratio of the planar extent F_{H} of the mushroom cap of the first metal area with respect to the planar extent F_{K} of the contact area in the depression of the cover layer. A range of this ratio of the planar extent F_{H}/F_{K} is in one case 1.05≦F_{H}/F_{K}≦1.5. The thickness d₁ in micrometers of the first metal area is in one case 2 μm≦d₁≦15 μm. This thickness d₁ depends, on the one hand, on what final height is to be achieved by the interconnecting element and, on the other hand, it depends on the thickness d₃ which the cover layer already has in connection with a removable photo resist layer.

If this cover layer is only a passivation layer of silicon nitride, thicknesses d₃ of up to 1 μm must be expected there so that a mushroom cap already forms at a deposition thickness d₁ of 2 μm of the first metal area. If, however, the cover layer is reinforced by a polyamide layer or by a photo resist layer, thicknesses d₃ or more than 20 μm can be achieved. In order to fill up the depression or the opening in such a reinforced cover layer with the material of the first material area, in one case of copper or of a copper alloy and, at the same time, still to form a mushroom cap, a greater thickness d₁ is advantageous.

In a further embodiment of the invention, it is provided that the contact terminal areas of the circuit support have copper or a copper alloy. Solder materials based on tin form intermetallic phases with the copper of the contact terminal areas ensure a higher temperature resistance of the second metal area. In this process, the intermetallic phase (Cu, Ni)₆ Sn₅ of a tin-containing solder material mixture forms in the second metal area in the boundary area between the first metal area and the second metal area. The greater the distance of the second metal area from this boundary area between the first metal area and the second metal area, the greater will be the proportion of copper of the copper-containing contact terminal area of the circuit support in the intermetallic phases.

Thus, an intermetallic phase Cu₆Sn₅ forms in a center area between the first metal area and the second metal area, which can be found most frequently in this center area. In the vicinity of the boundary area between the second metal area and the copper-containing contact terminal area, finally, the intermetallic phase Cu₃Sn forms which now has the highest proportion of copper atoms.

For the second metal area, a tin-containing lead-free solder material mixture which has SnAg solder material is used in one case. Solder material mixtures of SnAgCu are also possible in order to accelerate the formation of intermetallic phases. At the same time, the thickness d₂ of the second metal area is adjusted in such a manner that a complete penetration of this second metal area with intermetallic phases is possible within a suitable diffusion time. A range of the thickness d₂ of the second metal area is in one case about 5 μm≦d₂ 30 μm.

Looked at together with the thickness d₂ of the first metal area, with one embodiment of this invention both interconnecting elements have a minimum thickness of less than 10 μm can also be represented as interconnecting elements which can bridge a height of more than 50 μm. Such interconnecting elements are in one case used for semiconductor components with wiring substrate as circuit support, wherein the semiconductor chips are surface-mounted in flip chip technology on the contact terminal areas of a wiring structure on a top of the wiring substrate. These interconnecting elements or the contact areas of the semiconductor chips, respectively, are electrically connected to external contact areas on which external contacts are mounted, via the wiring structure and via through contacts through the wiring substrate.

Since both the first metal area and the second metal area can be deposited chemically or galvanically on a semiconductor wafer, it is possible to equip a multiplicity of semiconductor chips simultaneously with such interconnecting elements in a parallel process. For this reason, these interconnecting elements are in one case used for discrete semiconductor diodes, discrete semiconductor transistors, light-emitting diodes and/or radio-frequency transistors.

In one embodiment of the invention, the external dimensions of the semiconductor component are less than or equal to 1.0 mm×0.6 mm×0.4 mm in length×width×height (LWH) and in one case less than or equal to 0.6 mm×0.3 mm×0.4 mm. Since an immense number of interconnecting elements according to one embodiment of the invention of these semiconductor components with minimum dimensions are deposited on a semiconductor chip, the advantage of these interconnecting elements compared with solder balls of conventional flip chip technology can be clearly seen.

A method for producing a semiconductor wafer with interconnecting elements for a number of semiconductor chip positions, arranged in rows and columns on the semiconductor wafer, with surface-mountable interconnecting elements has the following method steps. Firstly, semiconductor chip structures for corresponding semiconductor components are produced in corresponding semiconductor component positions on the semiconductor wafer which have contact areas which are arranged in depressions of a cover layer.

This is followed by a selective galvanic deposition of a first metal on the contact areas by forming a mushroom shape which fills up the depressions in the cover layer and extends with a mushroom cap beyond the respective depression over areas of the edges of the depressions of the cover layer. After that, a second metal is selectively applied to the mushroom cap, which has a lead-free solder material which can form intermetallic phases with the metal of the contact terminal areas of the circuit support. As already mentioned above, a multiplicity of interconnecting elements can thus be prepared on a semiconductor wafer. In this process, these interconnecting elements can bridge a distance between 5 μm and 80 μm depending on the space between the semiconductor chip and the circuit support.

This variability, too, cannot be achieved by means of conventional solder balls for flip chip contacts. To produce suitable semiconductor chips from such a semiconductor wafer, standard technologies can be used unless the semiconductor chips are still to be thinned additionally. In this case, a technology is used which is called DBG (dicing before grinding). This technology of thinning the semiconductor wafer while simultaneously separating the semiconductor wafer into individual semiconductor chips is of advantage especially if it is intended to achieve the abovementioned minimum dimensions per semiconductor chip.

To then produce semiconductor components from these semiconductor chips, a wiring substrate with a multiplicity of circuit support positions with semiconductor component positions is provided wherein in each of the circuit support positions, a wiring structure is arranged which has contact terminal areas, the arrangement and size of which is adapted to the interconnecting elements on the semiconductor chip. The semiconductor chip can thus be soldered on directly with its interconnecting elements according to the invention in the circuit support positions of the wiring substrate for a number of semiconductor components, wherein the abovementioned intermetallic phases form which provide higher process temperature resistance for subsequent processing processes. After the semiconductor chips have been applied to the circuit support positions, the top of the wiring substrate with a multiplicity of semiconductor component positions can be packaged in a plastic package compound and subsequently the wiring substrate can then be separated into individual semiconductor components with the interconnecting elements according to the invention.

In addition to having more inexpensive production of a multiplicity of interconnecting elements, with this method semiconductor components can be produced by this means which have a minimum height and can still provide sufficiently large solder balls on the underside of the circuit support for surface-mounting on higher-level circuit supports. The wiring substrate or the wiring structure, respectively, ensures that the step size predetermined by the interconnecting elements between the semiconductor chip and the circuit support is not binding for the step size of the final external contacts of the semiconductor component.

In this method, nickel is in one case deposited first as diffusion barrier on the contact areas. This is followed by the deposition of copper or of a copper alloy as the first material area, wherein either a current-less metal deposition or a galvanic metal deposition can be used as deposition method. The second metal can also be selectively deposited, wherein in one case an SnAg solder mixture is deposited on the mushroom cap of the first metal area by means of a current-less metal deposition or a galvanic metal deposition. In these metal deposition processes, a multiplicity of interconnecting elements is produced in a parallel manner from interconnecting elements from the two metal areas if a semiconductor wafer is used to start with, and, naturally, a multiplicity of interconnecting elements can also be produced individually for each large-area semiconductor chip on large semiconductor chips.

An alternative for applying the second metal of an SnAg solder mixture can be a selective printing technique such as a jet printing technique which operates similarly to an inkjet printing technique, but for such a technique, greater tolerances must be provided for the dimensions of the interconnecting elements.

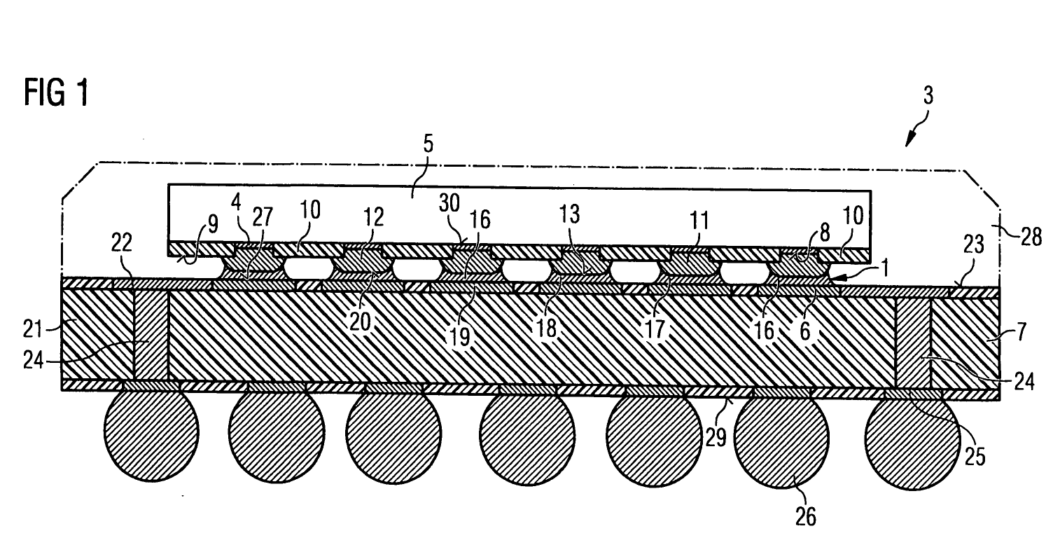

FIG. 1 illustrates a diagrammatic cross section through a semiconductor component 3 of an embodiment of the invention. The semiconductor component 3 has a circuit support 7 in the form of a wiring substrate 21, the wiring substrate 21 having on its underside 29 external contact areas 25 with external contacts 26 arranged thereon. These external contact areas 25 are connected via through contacts 24 to a wiring structure 22 arranged on the top 23 of the circuit support 7. A semiconductor chip 5 is arranged in flip-chip technology on contact terminal areas 6 of this wiring structure 22. For this purpose, the semiconductor chip 5 has on its active top 30 contact areas 4 which are electrically connected to the contact terminal areas 6 of the circuit support 7 via the interconnecting elements 1.

The contact areas 4 of the semiconductor chip 5 are arranged in depressions 8 of an insulating cover layer 10 and become freely accessible through the openings in the cover layer 10. The interconnecting element 1 has a first metal area 12 which fills up the depressions 8 and forms a mushroom shape 11 with a mushroom cap 13 which extends beyond the edge areas of the depressions 8 on a top 9 of the cover layer 10. This first metal area 12 has a metal which, on the one hand, completely closes the depression 8 by means of its mushroom shape 11 and, at the same time, projects beyond the depression 8 onto the cover layer 10 so that a second metal area 16, which in one case consists of a solder material 18, cannot reach the material of the contact areas 4 or on the semiconductor chip 5. It is also possible to produce mushroom shapes with a mushroom stalk by reinforcing the cover layer with a removable photo resist layer or polyamide layer, where the mushroom stalk protrudes over the cover layer.

A metal in a root area of the mushroom shape has not only a sealing function but this metal also forms a diffusion barrier for the material of the contact area 4 of the semiconductor chip 5 at increased temperature. At increased temperatures such as, for example, at the temperatures at which the solder material 18 of the second metal area 16 is soldered on, the material of the contact areas cannot diffuse into the first metal area 12. Neither can metal spikes grow into the first metal area during later migration loads. In one case, nickel or a nickel alloy is therefore used as diffusion barrier in the root area.

The first metal area 12 of copper or of a copper alloy is sufficiently ductile so that it can compensate for extreme shear stresses due to differences in the thermal expansion characteristic of the semiconductor chip 5 compared with the circuit support 7. The interconnecting element 1 itself forms intermetallic phases of the solder material 18 and the material of the contact terminal area 6 in the second metal area 16 so that a high-temperature-resistant interconnecting element 1 is produced between the contact area 4 of the semiconductor chip 5 and the contact terminal area 6 of the circuit support 7.

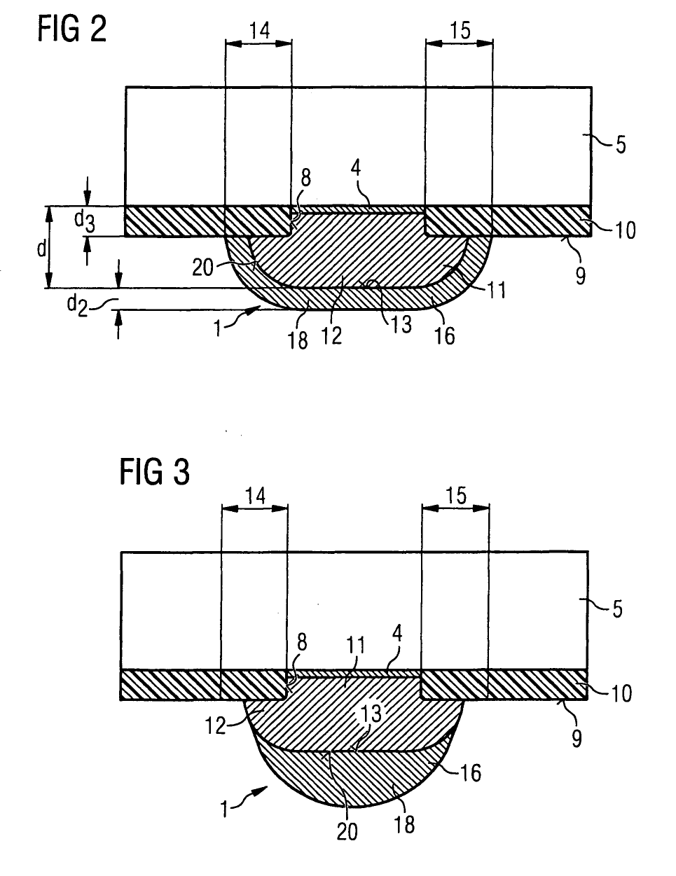

FIGS. 2 to 6 illustrate diagrammatic cross sections through a part area of an interconnecting element 1 during its production. Components having identical functions as in FIG. 1 are identified by the same reference symbols in FIGS. 2 to 6 and are not specially explained.

FIG. 2 illustrates a diagrammatic cross section through a contact terminal area of a semiconductor chip 5 after deposition of a first and a second metal area 12 and 16, respectively. In the present embodiment of the invention, this deposition is effected by electroplating or a so-called galvanic deposition. For this purpose, the semiconductor chip 5 or a semiconductor wafer with a multiplicity of semiconductor component positions with exposed contact areas 4 is placed in a galvanic bath and the semiconductor wafer or the semiconductor chip is connected to cathode potential so that nickel is first deposited as a first metal area 12 in the area of the freely accessible contact areas 4 of the semiconductor chip 5 in a nickel salt bath.

During this process, the nickel grows on in such a manner that it first fills up the depression 8 in the form of an opening in an insulating cover layer 10 and, when the deposition process is continued, a mushroom shape 11 of the first metal area 12 is created which extends with its mushroom cap 13 over the top 9 of the cover layer 10 in the edge areas 14 and 15 of the depression 8. This projection during the galvanic deposition of the first metal area 12 simultaneously creates a seal which makes it impossible for the solder material 18 of the second metal area 16 to be deposited later to come into contact with the contact area material of the contact area 4 of the semiconductor chip 5.

In the present embodiment of the invention, the material of the second metal area 16 is also applied to the first metal area 12 by means of a short galvanic deposition in a galvanic bath which contains the salts of the solder materials 18 to be deposited. These are preferably tin salts and silver salts which deposit a mixture of tin and silver on the mushroom cap 13 on the first metal area 12. Whereas the thickness d₁ of the first metal area 12 is greater than the thickness d₃ of the cover layer 10, the thickness d₂ of the second metal area 16 is dimensioned in such a manner that an almost complete conversion of the solder material 18 into intermetallic phases of the solder material 18 and the material of the contact terminal areas of the circuit support is produced. The thickness d₁ of the first metal area 12 can be between 2 μm≦d≦50 μm in dependence on the thickness d₃ of the cover layer 10. The projection of the first metal area 12 over the cover layer 10 provides a ratio of the planar extent F_{H} of the mushroom cap 13 of the first metal area 12 with respect to the planar extent F_{K} of the contact area 4 in the depression 8 of the cover layer 10 within a range from 1.05≦F_{H}/F_{K}≦1.5.

The solder material 18, as already mentioned above, in one case has a mixture of tin and silver. This mixture of tin and silver which is initially deposited uniformly on the mushroom cap 13 of the first metal area 12 and forms the boundary face 20 to the first metal area 12 is melted on in a next step and forms a solder material melt which is drop-shaped due to the surface tension as illustrated in FIG. 3.

FIG. 3 illustrates a diagrammatic cross section through the contact terminal area according to FIG. 2 after the second metal area 16 has been melted on. This drop-shaped formation on the boundary face 20 to the first metal area 12 takes place without a solder resist layer impeding the spreading 18 of the solder material. In production terms, this is an advantage since no patterned solder resist layer needs to be applied for the second metal area 16.

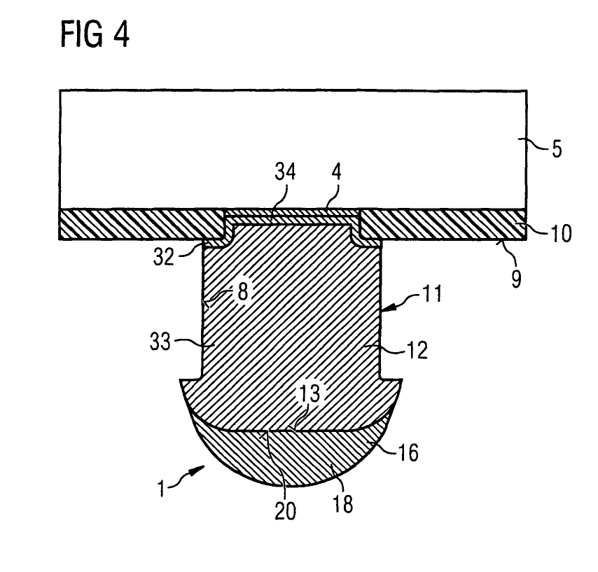

FIG. 4 illustrates a diagrammatic cross section through the contact terminal area of the mushroom-shaped interconnecting element 1. In this embodiment, a diffusion barrier 34 of a nickel layer is arranged in the root area 32 of the mushroom shape 11, which has the form of a mushroom stalk 33 before a first material area 12 is applied. The first material area 12 of copper or of a copper alloy fills an opening in a photo resist layer, which has been removed in the meantime, and forms the mushroom stalk 33 of the mushroom shape 11 of the first material area 12 which changes into a mushroom cap 13 above the photo resist layer, not illustrated, which is additionally covered by a lead-free solder material 18. It is thus possible to create slender resilient interconnecting elements of any height with minimum planar extent by varying the thickness of the photo resist layer. This solves the problems previously found in lead-free solder metallizations. In addition, it is possible to implement minimum step sizes between the interconnecting elements.

This is because the lead-free solder metallizations of Sn and Ag with bumps of sizes of up to 90 micrometers, previously used, exhibit an electro migration in packages of Si chip and circuit board substrates with occasionally severe increases in resistance due to the development of metallic phases of solder with the adjoining metals nickel and/or copper during the load tests and during the thermal cycling. The solder balls (bumps) establish the electrical connection between the Si chip and the circuit board substrate. Due to the difference in thermal expansion between chip and circuit board, the bumps are subject to strong transverse and shear stresses during the cyclic thermal loadings. These mechanical loads on Sn-containing bumps lead to permanent deformation including cracking. In addition, metals from the circuit board, e.g. Cu, Ni, Au are alloyed into the solder. These metallic phases in the solder can disturb the bump metallization to such an extent that the barrier of nickel breaks down under electro migration loads and, e.g., the aluminum metallization penetrates from the chip into the solder and the electrical resistance rises abruptly.

Producing a suitable shape of the first or base metallization 12 as illustrated in FIG. 4 in the form of a mushroom 11 provides a geometry which is only wetted in the area on the outer dome by a solder on the mushroom head 13. The solder does not flow off to the underside of the mushroom head 13 and over the stalk 33. Due to this behavior, the use of solder resist means becomes unnecessary.

Thus, the volume of solder on the base can be reduced to such an extent (10 μm-30 μm) that the solder is completely mixed through with the Cu of the contact terminal area of a circuit support to be soldered, and thus presents isothermal solidification. These newly formed metallic phases of Cu and Sn remain solid up to 450° C. Thus, this internal bump soldering cannot be melted again by later soldering of the component on higher-level circuit boards. The bump heights predetermined by the package technology (currently 70 μm-90 μm) can thus be implemented easily by lower or greater heights of the first or base metallization 12 of the mushroom stalk 33 of copper. Future heights of 10 μm to 20 μm for micro bumps or extreme heights such as 300 μm, which are normal for solder balls, can be implemented.

First or base and second or solder metallizations are produced by electroplating in opened resist patterns. The resist geometry (height and diameter of the opening) predetermines the height and the diameter of the base stalk or mushroom stalk 33. Further electroplating allows the metal to flow out of the resist opening and towards the sides in the form of a mushroom head or mushroom cap 13. The solder is electroplated in the same plant directly following the deposition of the mushroom heads 13 of the base metallization 12 with arbitrary thicknesses (e.g. 5 μm-−50 μm).

The costs for the production process of e.g. Cu mushrooms with nickel are less by about 6.00 euro per wafer compared with the lead-free solders.

This embodiment according to FIG. 4 has the following features due to the application of an elastic temperature-resistant first base metallization 12:

a) solder ball with lead-containing and lead-free solders, and are very easily wettable;

b) melting temperature >400° C.;

c) minimum plastic deformation;

d) geometric shape which prevents the running of the solder metallization (solder stopped by shaping);

e) production by electroplating in opened resist patterns (pattern plating);

so that:

1. the electrical resistance of the bump metallization is clearly reduced;

2. the stability under cyclic thermal loading and the electro migration resistance is increased (Ag, Cu, Au, Ni are more stable than Sn), penetration of chip aluminum into the solder is prevented by the mushroom bump;

3. the bump connection chip contact terminal area is temperature resistant up to 450° C. and is not impaired by further soldering of the components, and

4. a cost reduction of about 6.00 euro per wafer compared with solder bumps is achieved.

FIG. 5 illustrates a diagrammatic cross section through the contact terminal area with interconnecting element 1 according to FIG. 3 in an oblique section. As can be seen, a contact area 4 which has a thin metal coating is arranged on the silicon surface 31 as semiconductor material in the area of the depression 8 in the cover layer 10. On the contact terminal area 4, a relatively homogeneous phase of pure nickel is firstly arranged which also covers the edge areas 14 and 15 on the cover layer 10 with nickel with its mushroom shape 11. The boundary layer 20 forms the transition to the solder material 18, the solder material being clearly recognizable in the oblique section as a mixture of two metals, in one case tin and silver, due to the structuring of this area.

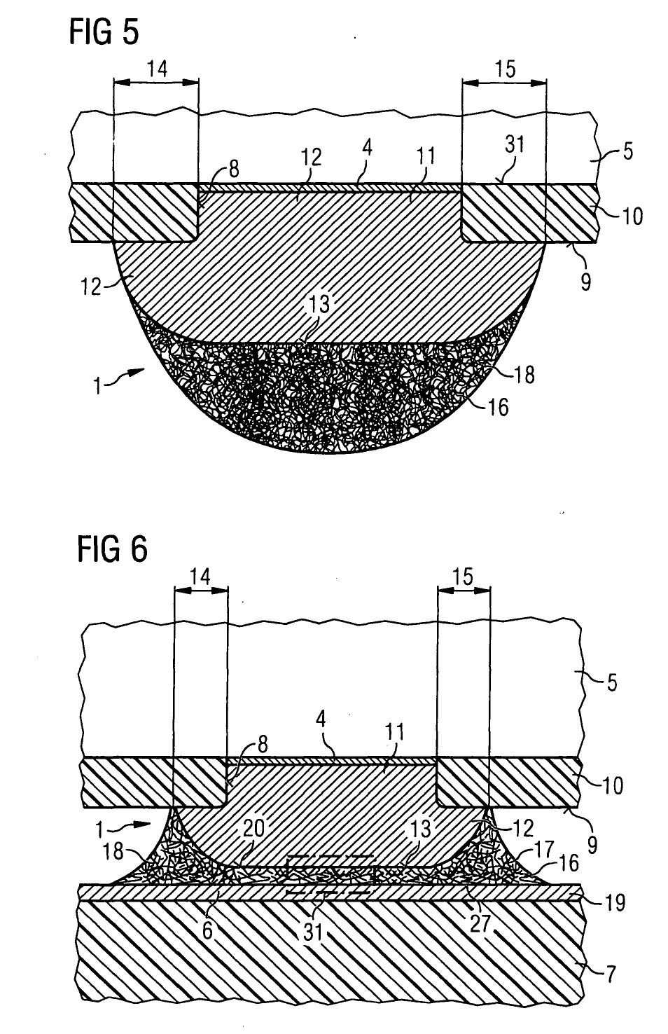

FIG. 6 illustrates a diagrammatic cross section through the contact terminal area after completion of the interconnecting element 1 by soldering onto a contact terminal area of a circuit support 7. The contact terminal area 6 of a circuit support 7 consists of a copper material which, with a tin component in the mixture of the SnAg solder mixture forms the intermetallic phases 17 and thus moves the remelting of this interconnecting element 1 towards higher temperatures of >400° C.

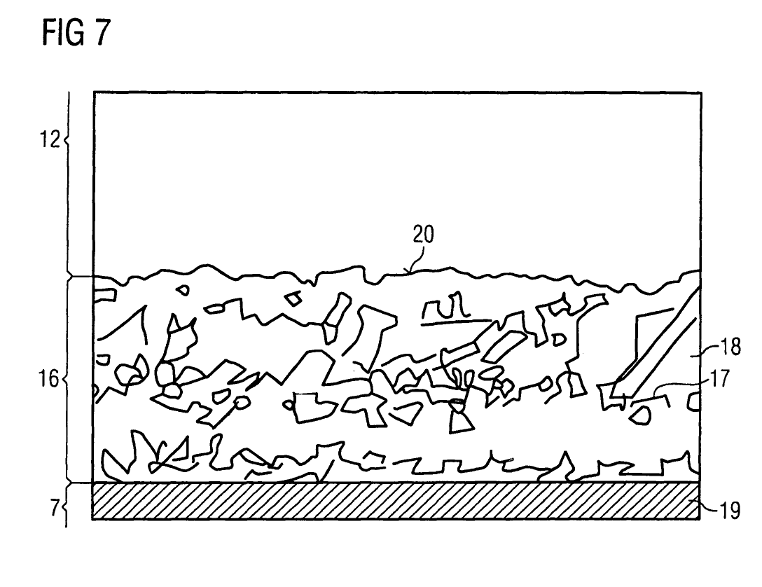

FIG. 7 illustrates a diagrammatic cross section through an enlarged detail of the interconnecting element 1 according to FIG. 6. The boundary face 20 between the nickel of the first metal area 12 and the solder material 18 of the second metal area 16 can be clearly seen, the second metal area 16 being located on a copper clad area of a circuit support. As a result, intermetallic phases which have a high proportion of copper such as, for example, Cu₃Sn, are produced in the vicinity of the boundary face 27 between the second metal area 16 and the contact terminal area 6 of a copper alloy. This area with Cu₃Sn as intermetallic phase is followed by an area with a greater proportion of tin in the intermetallic phase so that the intermetallic phase Cu₆Sn₅ forms in a center area between the first metal area 12 and the second metal area 16.

In the vicinity of the boundary layer 20 to the pure nickel of the first metal area 12, an intermetallic phase forms which also already includes nickel and exhibits the aggregate formula (Cu,Ni)₆Nn₅. This detailed view clearly illustrates that the second metal area 16 is completely penetrated by intermetallic phases 17. This can be achieved if the solder material layer is adjusted to a thickness d₂ of 5 μm≦d≦30 μm.

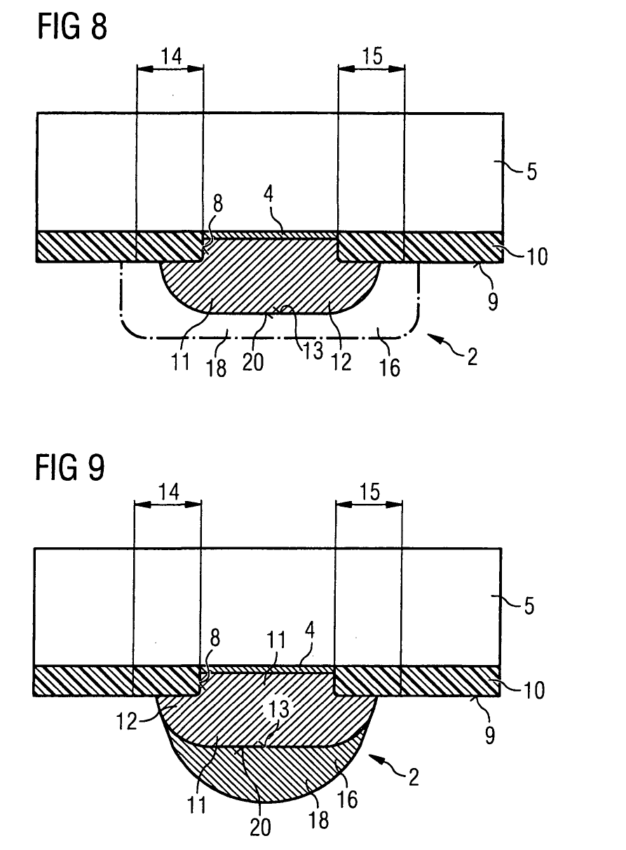

FIGS. 8 and 9 illustrate diagrammatic cross sections through a contact terminal area during the production of an interconnecting element 2 by means of an alternative method.

FIG. 8 illustrates a diagrammatic cross section through the contact terminal area after application of the first and second metal area 12 and 16, respectively. While the first metal area 12 with its mushroom shape is again galvanically deposited on the contact areas 4 in the depressions 8 of the cover layer 10, the second metal area 16 of solder material 18 has been applied by means of a printing method. For this purpose, a template printing or jet printing method can be used which, similarly to an inkjet printing, deposits solder material as second metal area 16 in the area of the first metal area 12. During the subsequent melting-on of the solder material 18, the characteristic solder material drop illustrated in FIG. 8 is produced on the boundary face 20 of the first metal area 12.

FIG. 9 illustrates a diagrammatic cross section through the contact terminal area after the second metal area 16 has been melted on. In principle, this creates a starting situation which, as in the first embodiment of the invention, is then suitable for creating an interconnecting element 2 with intermetallic phases to a contact terminal area of a circuit support. For this purpose, the semiconductor chip 5 which is illustrated partially in this case, can be applied to the circuit support and the prepared interconnecting elements 2 are aligned to corresponding contact terminal areas of the circuit support and are soldered onto the contact terminal areas at a soldering temperature within the range from 200° C. to 250° C., which produces intermetallic phases between the material of the second metal area 16 and the material of the contact terminal areas of the circuit support, not illustrated here, and creates a reliable high-temperature joint between a semiconductor chip and a circuit support.

Following this, the semiconductor chip 5 can be embedded in a plastic package compound 28 on the top 23 of the circuit support 7 for completing the semiconductor component, as illustrated in FIG. 1.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. The interconnecting elements for a semiconductor component comprising:
the interconnecting elements arranged between contact areas of a semiconductor chip of a semiconductor wafer and contact terminal areas of a circuit support;
wherein the contact areas on the semiconductor chip are arranged in depressions of a top of an insulating cover layer and are freely accessible;
wherein the interconnecting elements have a mushroom shape of a first metal area of the interconnecting element which fills up the depressions in the cover layer and extends with the mushroom cap beyond the respective depression over areas of the edges of the depressions in the cover layer; and
wherein, on the mushroom cap a second metal area is arranged which has high-melting intermetallic phases of metals of a solder material and the metal of the contact terminal areas of the circuit support.

2. The interconnecting elements as claimed in claim 1, wherein the contact areas of the semiconductor chip or of the semiconductor wafer have one or more of a group comprising nickel, aluminum, and gold.

3. The interconnecting elements as claimed in claim 1, wherein the first metal area of the interconnecting elements exhibits galvanically or chemically deposited nickel in a root area of the mushroom shape on the contact areas and on the cover layer at the edges of the depressions, and forms a diffusion barrier between the contact area and the first metal area.

4. The interconnecting elements as claimed in claim 3, wherein the first metal area forms the mushroom stalk of the mushroom shape and partially extends into the mushroom cap and has copper or a copper alloy.

5. The interconnecting elements as claimed in claim 1, wherein the second metal area has the intermetallic phase (Cu,Ni)₆Sn₅ of a tin-containing solder material mixture between the first metal area and the second metal area.

6. The interconnecting elements as claimed in claim 1, wherein the second metal area exhibits intermetallic phases with increasing copper content in the tin-containing lead-free solder material mixture in the direction of contact terminal areas exhibiting copper in a center area between the first metal area and contact terminal areas of the circuit support.

7. The interconnecting elements as claimed in claim 1, wherein the second metal area exhibits the intermetallic phase Cu₆Sn₅ of a tin-containing lead-free solder material mixture in the boundary area between copper-containing contact terminal areas and the second metal area.

8. The interconnecting elements as claimed in claim 1, wherein the second metal area exhibits the intermetallic phase Cu₃Sn of a tin-containing lead-free solder material mixture in the boundary area between copper-containing contact terminal areas and the second metal area.

9. The interconnecting elements as claimed in claim 1, wherein the tin-containing lead-free solder material mixture exhibits an SnAg solder mixture.

10. The interconnecting elements as claimed in claim 1, wherein the first metal area has a thickness d₁ of 2 μm≦d₁≦50 μm.

11. The interconnecting elements as claimed in claim 1, wherein the planar extent F_{H} of the mushroom cap of the first metal area, with respect to the planar extent F_{K} of the contact area in the depression of the cover layer, is 1.05≦F_{H}/F_{K}≦1.5.

12. The interconnecting elements as claimed in claim 1, wherein the second metal area has a thickness d₂ of 3 μm≦d₂≦30 μm.

13. The interconnecting elements as claimed in claim 1, for semiconductor components with wiring substrate as circuit support, wherein the semiconductor chips with the interconnecting elements are surface-mounted in flip chip technology on the contact terminal areas of a wiring structure on a top of the wiring substrate and are electrically connected to external contact areas, on which external contacts are mounted, via through contacts through the wiring substrate.

14. A semiconductor component comprising:
interconnecting elements arranged between contact areas of a semiconductor chip of a semiconductor wafer and contact terminal areas of a circuit support,
wherein the contact areas on the semiconductor chip are arranged in depressions of a top of an insulating cover layer and are freely accessible;
wherein the interconnecting elements have a mushroom shape of a first metal area of the interconnecting element which fills up the depressions in the cover layer and extends with the mushroom cap beyond the respective depression over areas of the edges of the depressions in the cover layer; and
wherein, on the mushroom cap, a second metal area is arranged which has high-melting intermetallic phases of metals of a solder material and the metal of the contact terminal areas of the circuit support.

15. The semiconductor component as claimed in claim 14, wherein the contact areas of the semiconductor chip or of the semiconductor wafer have one or more of a group comprising nickel, aluminum, and gold.

16. The semiconductor component as claimed in claim 14, wherein the first metal area of the interconnecting elements exhibits galvanically or chemically deposited nickel on the contact areas and on the cover layer at the edges of the depressions.

17. The semiconductor component as claimed in claim 14, wherein the contact terminal areas of the circuit support have copper or a copper alloy.

18. The semiconductor component as claimed in claim 14, wherein the second metal area has the intermetallic phase (Cu,Ni)₆Sn₅ of a tin-containing solder material mixture in the boundary area between the first metal area and the second metal area.

19. The semiconductor component as claimed in claim 14, wherein the second metal area exhibits intermetallic phases with increasing copper content in the tin-containing lead-free solder material mixture in the direction of contact terminal areas exhibiting copper in a center area between the first metal area and contact terminal areas of the circuit support.

20. The semiconductor component as claimed in one of claim 14, wherein the second metal area exhibits the intermetallic phase Cu₆Sn₅ of a tin-containing lead-free solder material mixture in the boundary area between copper-containing contact terminal areas and the second metal area.

21. The semiconductor component as claimed in claim 14, wherein the second metal area exhibits the intermetallic phase Cu₃Sn of a tin-containing lead-free solder material mixture in the boundary area between copper-containing contact terminal areas and the second metal area.

22. The semiconductor component as claimed in claim 14, wherein the tin-containing lead-free solder material mixture exhibits an SnAg solder mixture.

23. The semiconductor component as claimed in claim 14, wherein the first metal area has a thickness d₁ of 2 μm≦d₁≦50 μm.

24. The semiconductor component as claimed in claim 14, wherein the planar extent F_{H} of the mushroom cap of the first metal area, with respect to the planar extent F_{K} of the contact area in the depression of the cover layer, is 1.05≦F_{H}/F_{K}≦1.5.

25. The semiconductor component as claimed in claim 14, wherein the second metal area has a thickness d₂ of 5 μm≦d₂≦30 μm.

26. The semiconductor component as claimed in claim 14, wherein the semiconductor component has a semiconductor diode, a semiconductor transistor, light-emitting diodes and/or RF transistors.

27. The semiconductor component as claimed in claim 14, wherein the dimensions of the semiconductor component are less than or equal to 1.0 mm×0.6 mm×0.4 mm in length×width×height.

28. A method for producing a semiconductor wafer with interconnecting elements for a number of semiconductor chip positions, arranged in rows and columns on the semiconductor wafer, with surface-mountable interconnecting elements, the method comprising:
producing semiconductor chip structures for semiconductor components on the top of the semiconductor wafer in semiconductor chip positions, which have contact areas which are arranged in depressions of a cover layer;
selectively galvanically depositing a first metal on the contact areas by forming a mushroom shape which fills up the depressions in the cover layer and extends with a mushroom cap beyond the respective depression over areas of the edges of the depressions of the cover layer; and
selectively applying a second metal to the mushroom cap, which has a lead-free solder material which can form intermetallic phases with the metal of the contact terminal areas of the circuit support.

29. A method for producing a number of semiconductor chips with surface-mountable interconnecting elements to a circuit support, the method comprising:
producing semiconductor chip structures for semiconductor components on the top of the semiconductor wafer in semiconductor chip positions, which have contact areas which are arranged in depressions of a cover layer;
selectively galvanically depositing a first metal on the contact areas by forming a mushroom shape which fills up the depressions in the cover layer and extends with the mushroom cap beyond the respective depression over areas of the edges of the depressions of the cover layer;
selectively applying a second metal to the mushroom cap, which has a lead-free solder material which can form intermetallic phases with the metal of the contact terminal areas of the circuit support; and
separating the semiconductor wafer into semiconductor chips with surface-mountable interconnecting elements.

30. A method for producing a semiconductor component with interconnecting elements between a semiconductor chip and a circuit support, the method comprising:
producing semiconductor chip structures for semiconductor components on the top of the semiconductor wafer in semiconductor chip positions, which have contact areas which are arranged in depressions of a cover layer;
selectively galvanically depositing a first metal on the contact areas by forming a mushroom shape which fills up the depressions in the cover layer and extends with the mushroom cap beyond the respective depression over areas of the edges of the depressions of the cover layer;
selectively applying a second metal to the mushroom cap, which has a lead-free solder material which can form intermetallic phases with the metal of the contact terminal areas of the circuit support;
separating the semiconductor wafer into semiconductor chips with surface-mountable interconnecting elements;
applying the semiconductor chips in semiconductor component positions of a circuit support by diffusion soldering the interconnecting elements onto contact terminal areas in the semiconductor component positions;
embedding individual or a number of semiconductor chips into a plastic package compound; and
separating the circuit support into individual semiconductor components.

31. The method as claimed in claim 28, wherein the selective depositing of the first metal, is nickel, on the contact areas, and takes place by means of a currentless metal deposition.

32. The method as claimed in claim 28, wherein the selective depositing of the first metal is nickel, on the contact areas, and takes place by means of a galvanic metal deposition.

33. The method as claimed in claim 28, wherein the second metal is produced by selectively depositing an SnAg solder mixture on the mushroom cap of the first metal by means of a currentless metal deposition.

34. The method as claimed in claim 28, wherein the second metal is produced by selectively depositing an SnAg solder mixture of the mushroom cap of the first metal by means of a galvanic metal deposition.

35. The method as claimed in claim 28, wherein the second metal is applied to the mushroom cap of the first metal by selective printing techniques of an SnAg solder mixture.

36. The method as claimed in claim 30, wherein intermetallic phases of one of a group comprising:
(Cu,Ni)₆Sn₅, Cu₆Sn₅ and Cu₃Sn, form when the second metal is soldered onto copper-containing contact terminal areas.
